(19) United States
(12) Patent Application Publication
(10) Pub. No.: US 2024/0321559 A1
(43) Pub. Date: Sep. 26, 2024

(54) PLASMA PROCESSING APPARATUS

(71) Applicant: Tokyo Electron Limited, Tokyo (JP)

(72) Inventor: Satoshi TAGA, Miyagi (JP)

(73) Assignee: Tokyo Electron Limited, Tokyo (JP)

(21) Appl. No.: 18/609,340

(22) Filed: Mar. 19, 2024

(30) Foreign Application Priority Data
Mar. 20, 2023 (JP) 2023-044611
Jan. 11, 2024 (JP) 2024-002471

(51) Int. Cl. H01J 37/32; G05D 7/06; G05D 9/12

(52) U.S. Cl. CPC H01J 37/32522; G05D 7/0676; G05D 9/12; H01J 2237/002

(57) ABSTRACT

A technique for reducing a pressure at which a heat transfer medium is supplied to a flow path is provided. In an exemplary embodiment, a plasma processing apparatus is provided. The plasma processing apparatus includes a chamber, a plasma generator, a temperature adjustment target, and a supply. The supply supplies a heat transfer medium to the flow path and includes a first tank, a second tank, a pump, and a heat exchanger. The first tank stores the heat transfer medium and is connected to the flow path via a first pipe. The second tank stores the heat transfer medium, is connected to the flow path via a second pipe, and is connected to the first tank via a third pipe. The second tank is disposed at a position lower than a position of the first tank.

### CROSS-REFERENCE TO RELATED APPLICATIONS

This application claims priority under 35 U.S.C. § 119(a) to Japanese Patent Application No. 2023-044611, filed on Mar. 20, 2023 and Japanese Patent Application No. 2024-002471, filed on Jan. 11, 2024, the entire contents of each are incorporated herein by reference.

### TECHNICAL FIELD

Exemplary embodiments of the present disclosure relate to a plasma processing apparatus.

### BACKGROUND

A plasma processing apparatus is used in plasma processing with respect to a substrate. The plasma processing apparatus includes a chamber and a base disposed within the chamber. The base has a flow path therein. In JP2005-079539A to be described below, a plasma processing apparatus includes a compressor for supplying a heat transfer medium to a flow path. The heat transfer medium compressed by the compressor is supplied to the flow path.

### CITATION LIST

### Patent Documents

Patent Document 1: JP2005-079539A

### SUMMARY

The present disclosure provides a technique for reducing a pressure at which a heat transfer medium is supplied to a flow path.

In an exemplary embodiment, a plasma processing apparatus is provided. The plasma processing apparatus includes a chamber, a plasma generator, at least one temperature adjustment target, and a supply. The plasma generator is configured to generate plasma from a gas within the chamber. The at least one temperature adjustment target has a flow path therein. The at least one temperature adjustment target constitutes a part of the chamber or is disposed within the chamber. The supply is configured to supply a heat transfer medium to the flow path. The supply includes a first tank, a second tank, a pump, and a heat exchanger. The first tank is configured to store the heat transfer medium therein. The first tank is connected to the flow path via a first pipe. The second tank is configured to store the heat transfer medium therein. The second tank is connected to the flow path via a second pipe, and is connected to the first tank via a third pipe. The second tank is disposed at a position lower than a position of the first tank. The pump is connected between the third pipe and the second tank. The pump is configured to pump the heat transfer medium stored in the second tank to the first tank via the third pipe. The heat exchanger is provided upstream of the flow path. The heat exchanger is configured to adjust a temperature of the heat transfer medium.

According to the exemplary embodiment, a pressure at which the heat transfer medium is supplied to the flow path is reduced.

### BRIEF DESCRIPTION OF DRAWINGS

FIG. 1 is a diagram for explaining an example of a configuration of a plasma processing system.

FIG. 2 is a view for explaining an example of a configuration of a capacitively-coupled plasma processing apparatus.

FIG. 3 is a diagram illustrating a configuration of a supply and a temperature adjustment target in a plasma processing apparatus according to an exemplary embodiment.

FIG. 4 is a view illustrating a configuration of a supply and a temperature adjustment target in a plasma processing apparatus according to another exemplary embodiment.

FIG. 5 is a flowchart of a method of supplying a heat transfer medium according to an exemplary embodiment.

FIG. 6 is a flowchart illustrating an example of a step STb illustrated in FIG. 5.

### DETAILED DESCRIPTION

Hereinafter, various exemplary embodiments will be described in detail with reference to the drawings. Further, like reference numerals will be given to like or corresponding parts throughout the drawings.

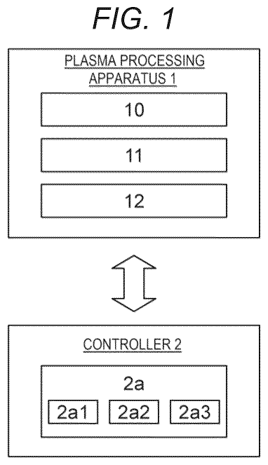

FIG. 1 is a diagram for explaining an example of a configuration of a plasma processing system. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to a gas supply 20 which will be described later, and the gas exhaust port is connected to an exhaust system 40 which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave-excited plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2al, a storage unit 2a2, and a communication interface 2a3. The controller 2 is implemented by, for example, a computer 2a. The processor 2al may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2al. The medium may be various storing media readable by the computer 2a, or may be a communication line connected to the communication interface 2a3. The processor 2al may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

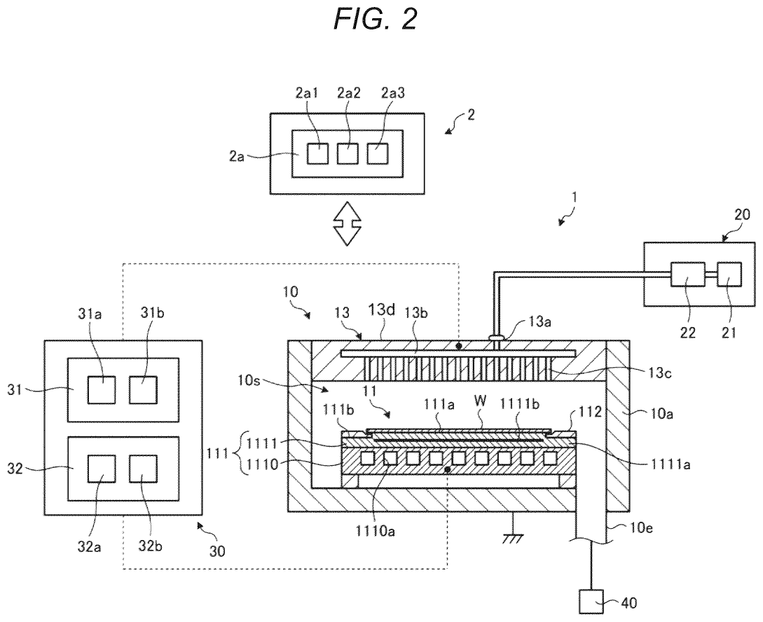

Hereinafter, a configuration example of a capacitively-coupled plasma processing apparatus as an example of the plasma processing apparatus 1 will be described. FIG. 2 is a view for explaining an example of a configuration of a capacitively-coupled plasma processing apparatus.

The capacitively-coupled plasma processing apparatus 1 includes the plasma processing chamber 10, the gas supply 20, a power source 30, and the exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a RF power source 31 and/or a DC power source 32 to be described later may be disposed in the ceramic member 1111a. In this case, the at least one RF/DC electrode functions as the lower electrode. In a case where a bias RF signal and/or a DC signal to be described later are supplied to at least one RF/DC electrode, the RF/DC electrode is also referred to as a bias electrode. The conductive member of the base 1110 and the at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes an RF power source 31 coupled to plasma processing chamber 10 via at least one impedance matching circuit. The RF power source 31 is configured to supply at least one RF signal (e.g., RF power) to at least one lower electrode and/or at least one upper electrode. As a result, plasma is formed from at least one processing gas supplied into the plasma processing space 10s. Accordingly, the RF power source 31 may function as at least a part of the plasma generator 12. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (e.g., source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (e.g., bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first DC signal is applied to at least one lower electrode. In one embodiment, the second DC generator 32b is configured to be connected to at least one upper electrode to generate a second DC signal. The generated second DC signal is applied to at least one upper electrode.

In various embodiments, the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

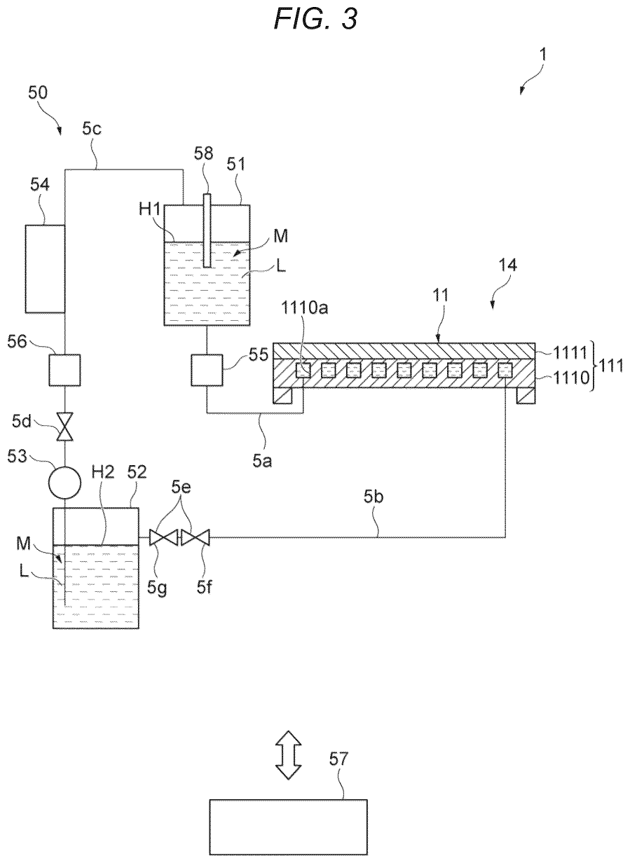

The plasma processing apparatus 1 includes at least one temperature adjustment target. The at least one temperature adjustment target constitutes a part of the chamber 10 or is disposed within the chamber 10. In one embodiment, the at least one temperature adjustment target may include the sidewall 10a of the chamber 10. In one embodiment, the at least one temperature adjustment target may include at least one of the substrate support 11 and an upper electrode 13d. In one embodiment, the at least one temperature adjustment target may include the substrate support 11. The at least one temperature adjustment target has a flow path therein. Hereinafter, the plasma processing apparatus 1 that includes a single temperature adjustment target 14 will be described with reference to FIG. 3. However, the plasma processing apparatus 1 may include a plurality of temperature adjustment targets 14.

FIG. 3 is a diagram illustrating a configuration of a supply and a temperature adjustment target in a plasma processing apparatus according to an exemplary embodiment. In the example illustrated in FIG. 3, the temperature adjustment target 14 includes the substrate support 11. The temperature adjustment target 14 has the flow path 1110a therein. A supply 50 is configured to supply a heat transfer medium M to the flow path 1110a. In one embodiment, the heat transfer medium M may be a heat transfer liquid L.

The supply 50 includes a first tank 51, a second tank 52, a pump 53, and a heat exchanger 54. The first tank 51 is configured to store the heat transfer medium M therein. The first tank 51 is connected to the flow path 1110a via a first pipe 5a. The heat transfer medium M stored in the first tank 51 is supplied to the flow path 1110a via the first pipe 5a.

The second tank 52 is configured to store the heat transfer medium M therein. The second tank 52 is connected to the flow path 1110a via a second pipe 5b, and is connected to the first tank 51 via a third pipe 5c. The second tank 52 is disposed at a position lower than a position of the first tank 51. In an example, the position of the second tank 52 is lower than the position of the first tank 51 within a range of 0.1 m or more and 10 m or less. The heat transfer medium M retrieved from the flow path 1110a is stored in the second tank 52. In one embodiment, the first tank 51 and the second tank 52 are disposed outside the chamber 10 so as to set a pressure inside each of the first tank 51 and the second tank 52 to be an atmospheric pressure.

The pump 53 is connected between the third pipe 5c and the second tank 52. The pump 53 is configured to pump the heat transfer medium M stored in the second tank 52 to the first tank 51 via the third pipe 5c. The heat transfer medium M stored in the second tank 52 is retrieved to the first tank 51 by the pump 53. In the supply 50, the heat transfer medium M circulates through the first tank 51, the flow path 1110a, and the second tank 52. The pump 53 may be disposed at a position lower than a maximum height position of the second tank 52.

The heat exchanger 54 is configured to adjust a temperature of the heat transfer medium M in the supply 50. The heat exchanger 54 is disposed upstream of the flow path 1110a. In the example illustrated in FIG. 3, the heat exchanger 54 is disposed along the third pipe 5c to adjust a temperature of the heat transfer medium M in the third pipe 5c. The heat exchanger 54 may be disposed along the first pipe 5a.

In the plasma processing apparatus 1, the second tank 52 is located at a lower position than the first tank 51, and thus the heat transfer medium M moves from the first tank 51 toward the second tank 52 due to an action of gravity. Therefore, the heat transfer medium M is supplied to the flow path 1110a at a considerably low pressure. Therefore, deformation of the temperature adjustment target 14 (in an example, the base 1110 of the substrate support 11) is prevented.

In one embodiment, the first pipe 5a may be connected to the first tank 51 at a position higher than a position of the flow path 1110a as in the example illustrated in FIG. 3. The second pipe 5b may be connected to the second tank 52 at a position lower than the position of the flow path 1110a.

In one embodiment, the supply 50 may include a first flow rate meter 55, a second flow rate meter 56, a flow rate adjustment valve 5d, and a controller 57 as in the example illustrated in FIG. 3. The first flow rate meter 55 is configured to measure a first flow rate of the heat transfer medium M in the first pipe 5a. In an example, the first flow rate meter 55 is connected to the first pipe 5a. The second flow rate meter 56 is configured to measure a second flow rate of the heat transfer medium M in the third pipe 5c. In an example, the second flow rate meter 56 is connected between the third pipe 5c and the pump 53. The flow rate adjustment valve 5d is connected between the pump 53 and the first tank 51. The flow rate adjustment valve 5d is configured to adjust a flow rate of the heat transfer medium M in the third pipe 5c. The flow rate adjustment valve 5d is, for example, a needle valve. In an example, the flow rate adjustment valve 5d is connected between the third pipe 5c and the pump 53. The controller 57 is configured to adjust the flow rate adjustment valve 5d to reduce or eliminate a difference between the first flow rate and the second flow rate. The controller 57 may be configured to automatically adjust the flow rate adjustment valve 5d. The controller 57 may be configured to be operated by an operator to adjust the flow rate adjustment valve 5d.

For example, when the first flow rate is larger than the second flow rate, the controller 57 adjusts the flow rate adjustment valve 5d to increase the second flow rate. When the first flow rate is smaller than the second flow rate, the controller 57 adjusts the flow rate adjustment valve 5d to reduce the second flow rate. As a result, the difference between the first flow rate and the second flow rate is reduced or eliminated. Since the second flow rate is a flow rate of the heat transfer medium M retrieved to the first tank 51 and the first flow rate is a flow rate of the heat transfer medium M supplied from the first tank 51 to the flow path 1110a, an amount of the heat transfer medium M stored in the first tank 51 is stabilized.

In one embodiment, the supply 50 may include at least one valve 5e. Hereinafter, the supply 50 including a plurality of valves 5e will be described. However, the supply 50 may include one valve 5e. The plurality of valves 5e are connected between the second pipe 5b and the second tank 52. In an example, the plurality of valves 5e are connected to the second pipe 5b. In one embodiment, the plurality of valves 5e may include a shutoff valve 5f and/or a flow rate adjustment valve 5g. In one embodiment, the shutoff valve 5f and the flow rate adjustment valve 5g are connected in series between the second pipe 5b and the second tank 52. As in the example illustrated in FIG. 3, the shutoff valve 5f and the flow rate adjustment valve 5g are connected in series to the second pipe 5b. The shutoff valve 5f may be opened and closed by the controller 57.

The flow rate adjustment valve 5g is configured to adjust a flow rate of the heat transfer medium M in the second pipe 5b. The flow rate adjustment valve 5g may be adjusted by the controller 57. When the flow rate adjustment valve 5g is adjusted to increase the flow rate of the heat transfer medium M in the second pipe 5b, the first flow rate in the first pipe 5a connected via the flow path 1110a also increases. When the flow rate adjustment valve 5g is adjusted to reduce the flow rate of the heat transfer medium M in the second pipe 5b, the first flow rate in the first pipe 5a connected via the flow path 1110a is also reduced. The flow rate adjustment valve 5g is, for example, a needle valve.

In one embodiment, the supply 50 may include a liquid level sensor 58. The liquid level sensor 58 is configured to measure a height position of a liquid level of the heat transfer medium M in one of the first tank 51 and the second tank 52. In the example illustrated in FIG. 3, the liquid level sensor 58 is configured to measure a height position H1 of the liquid level of the heat transfer medium M in the first tank 51. In this case, the liquid level sensor 58 is disposed in the first tank 51. The controller 57 is configured to adjust the flow rate adjustment valve 5d to maintain the height position H1 of the liquid level measured by the liquid level sensor 58 within a designated range.

For example, when the height position H1 of the liquid level measured by the liquid level sensor 58 is higher than the designated range, the controller 57 adjusts the flow rate adjustment valve 5d to reduce the second flow rate. When the second flow rate is reduced, the amount of the heat transfer medium M stored in the first tank 51 decreases, and thus the height position H1 of the liquid level becomes lower. As a result, the height position H1 of the liquid level may be maintained within the designated range.

For example, when the height position H1 of the liquid level measured by the liquid level sensor 58 is lower than the designated range, the controller 57 adjusts the flow rate adjustment valve 5d to increase the second flow rate. When the second flow rate increases, an amount of the heat transfer medium M stored in the first tank 51 increases, and thus the height position H1 of the liquid level becomes higher. As a result, the height position H1 of the liquid level may be maintained within the designated range.

In one embodiment, the controller 57 may be configured to adjust the flow rate adjustment valve 5d to reduce or eliminate the difference between the first flow rate and the second flow rate when the height position H1 of the liquid level is within the designated range. The controller 57 may be configured to maintain the height position H1 of the liquid level within the designated range when the height position H1 of liquid level is outside the designated range. A balance between the amount of the heat transfer medium M stored in the first tank 51 and the amount of the heat transfer medium M stored in the second tank 52 is adjusted.

In an example, in a facility where the plasma processing apparatus 1 is disposed, the first tank 51, the heat exchanger 54, the first flow rate meter 55, and the second flow rate meter 56 may be disposed on a first floor on which the chamber 10 and the substrate support 11 are disposed. In an example, the first tank 51, the heat exchanger 54, the first flow rate meter 55, and the second flow rate meter 56 may constitute a single unit as a reservoir. In the facility where the plasma processing apparatus 1 is disposed, the second tank 52, the pump 53, the shutoff valve 5f, and the flow rate adjustment valve 5g may be disposed on a second floor below the first floor. In an example, the second tank 52, the pump 53, the shutoff valve 5f, and the flow rate adjustment valve 5g may constitute a single unit as a receiver.

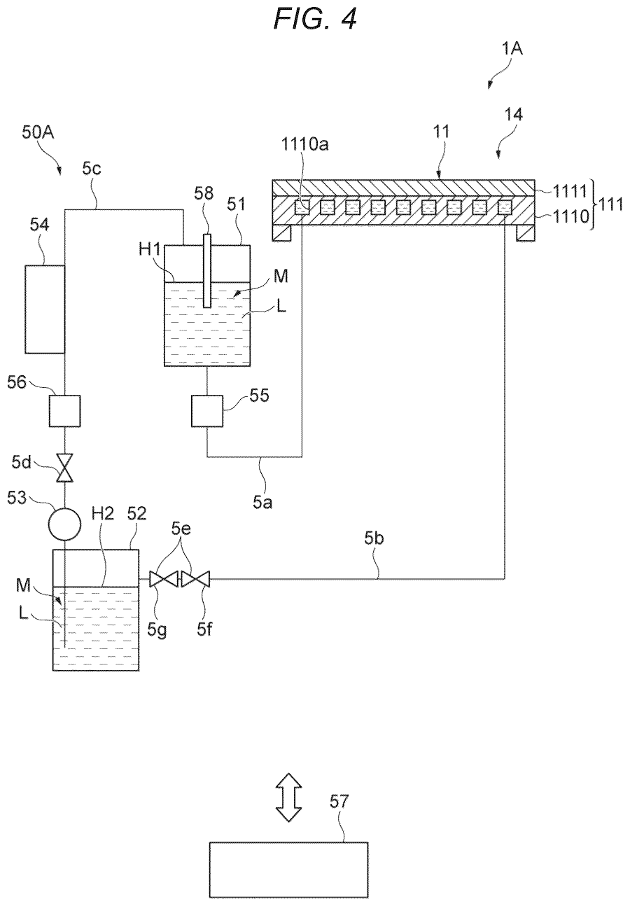

Hereinafter, configurations of a supply and a temperature adjustment target in a plasma processing apparatus according to another exemplary embodiment will be described with reference to FIG. 4. FIG. 4 illustrates a supply 50A and the temperature adjustment target 14 in a plasma processing apparatus 1A according to the other exemplary embodiment. Hereinafter, the supply 50A of the plasma processing apparatus 1A illustrated in FIG. 4 will be described in view of differences from the supply 50 of the plasma processing apparatus 1.

In the supply 50A, the first pipe 5a is connected to the first tank 51 at a position lower than a position of the flow path 1110a. In the example illustrated in FIG. 4, the position of the flow path 1110a is higher than the position of the first tank 51. In an example, the position of the flow path 1110a is higher than a position where the first pipe 5a is connected to the first tank 51 within a range of 0 m or more and 2 m or less. In this case, the heat transfer medium M is also supplied from the first tank 51 to the flow path 1110a due to a siphon phenomenon that occurs when the heat transfer medium M is retrieved from the flow path 1110a to the second tank 52.

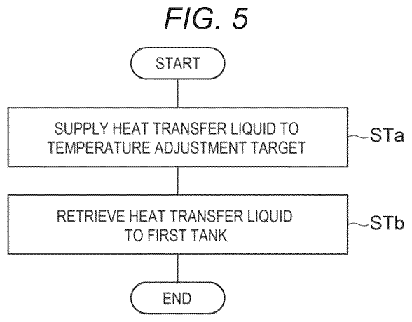

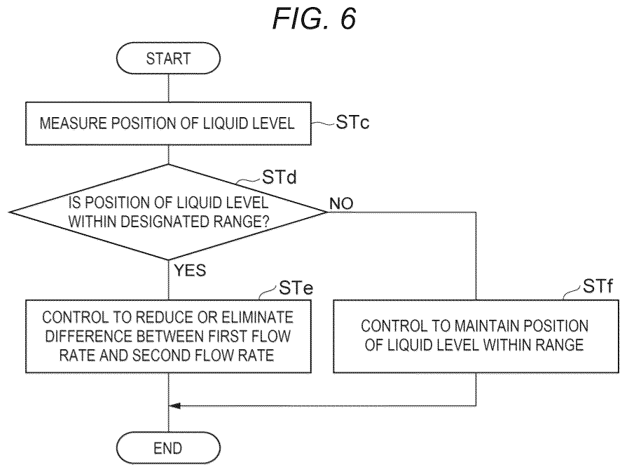

Hereinafter, a method of supplying the heat transfer medium will be described with reference to FIGS. 5 and 6. FIG. 5 is a flowchart of a method of supplying a heat transfer medium according to an exemplary embodiment. FIG. 6 is a flowchart illustrating an example of a step STb illustrated in FIG. 5.

The method of supplying the heat transfer medium illustrated in FIG. 5 (hereinafter referred to as a method MT) may be performed using any one of the various plasma processing apparatuses described above. The method MT includes a step STa and the step STb. In the step STa, the heat transfer medium M is supplied to the flow path 1110a. In the step STb, the heat transfer medium M is retrieved to the first tank 51. In an example, the heat transfer medium M is supplied from the first tank 51 to the flow path 1110a, and is retrieved from the second tank 52 to the first tank 51.

In one embodiment, the step STb may include steps STc, STd, STe, and STf as illustrated in FIG. 6. In the step STc, a height position of a liquid level is measured. In the plasma processing apparatuses 1 and 1A, the liquid level sensor 58 measures the height position H1 of the liquid level.

In the subsequent step STd, it is determined whether the height position of the liquid level is within a designated range. In the plasma processing apparatuses 1 and 1A, it is determined whether the height position H1 of the liquid level is within the designated range. When it is determined that the height position of the liquid level is within the designated range, the processing proceeds to the step STe.

In the step STe, the first flow rate and/or the second flow rate are controlled to reduce or eliminate a difference between the first flow rate and the second flow rate. In the plasma processing apparatuses 1 and 1A, the second flow rate is controlled by adjusting the flow rate adjustment valve 5d, and thus the difference between the first flow rate and the second flow rate is reduced or eliminated.

When it is determined that the height position of the liquid level is outside the designated range, the processing proceeds to the step STf. In the step STf, the first flow rate and/or the second flow rate are controlled to maintain the height position of the liquid level within the designated range. In the plasma processing apparatuses 1 and 1A, the second flow rate is controlled by adjusting the flow rate adjustment valve 5d, and thus the height position H1 of the liquid level is maintained within the designated range.

While various exemplary embodiments have been described above, various additions, omissions, substitutions and changes may be made without being limited to the exemplary embodiments described above. Indeed, the embodiments described herein may be embodied in a variety of other forms.

In the plasma processing apparatus according to another embodiment, the liquid level sensor 58 may be configured to measure a height position H2 of a liquid level of the heat transfer medium M in the second tank 52. In this case, the liquid level sensor 58 is disposed in the second tank 52. The controller 57 is configured to adjust the flow rate adjustment valve 5d to maintain the height position H2 of the liquid level measured by the liquid level sensor 58 within a designated range.

For example, when the height position H2 of the liquid level measured by the liquid level sensor 58 is higher than the designated range, the controller 57 adjusts the flow rate adjustment valve 5d to increase the first flow rate. As the first flow rate increases, an amount of the heat transfer medium M stored in the second tank 52 decreases, and thus the height position H2 of the liquid level becomes lower. As a result, the height position H2 of the liquid level may be maintained within the designated range.

For example, when the height position H2 of the liquid level measured by the liquid level sensor 58 is lower than the designated range, the controller 57 adjusts the flow rate adjustment valve 5d to reduce the first flow rate. As the first flow rate is reduced, the amount of the heat transfer medium M stored in the second tank 52 increases, and thus the height position H2 of the liquid level becomes higher. As a result, the height position H2 of the liquid level may be maintained within the designated range.

In the plasma processing apparatus according to still another embodiment, the supply may not include the first flow rate meter 55 and/or the second flow rate meter 56. The supply may include the liquid level sensor 58. In this case, the controller 57 is configured to maintain a height position of a liquid level within a designated range.

In the plasma processing apparatus according to still another embodiment, the supply may not include the flow rate adjustment valve 5d. In this case, the controller 57 is configured to control the pump 53 to reduce or eliminate a difference between the first flow rate and the second flow rate. For example, when the first flow rate is larger than the second flow rate, the controller 57 controls the pump 53 to increase a flow rate of the heat transfer medium M pumped by the pump 53. When the first flow rate is smaller than the second flow rate, the controller 57 controls the pump 53 to reduce the flow rate of the heat transfer medium M pumped by the pump 53.

In one embodiment, the controller 57 may be configured to control the pump 53 to reduce or eliminate a difference between the first flow rate and the second flow rate when the height position H1 of a liquid level is within a designated range. The controller 57 may be configured to control the pump 53 to maintain the height position H1 of the liquid level within the designated range when the height position H1 of the liquid level is outside the designated range.

In one embodiment, when at least one temperature adjustment target includes the upper electrode 13d, the upper electrode 13d has a flow path therein. In an example, when the upper electrode 13d includes a first electrode constituting a top plate of the chamber 10 and a second electrode disposed on the first electrode, the second electrode may have a flow path therein.

In one embodiment, the heat transfer medium M may not be the heat transfer liquid L. The heat transfer medium M may be a fluid heavier than the atmosphere.

In one embodiment, a pump having a lower output than a pump used in a related-art supply may be used as the pump 53.

Hereinafter, various exemplary embodiments included in the present disclosure will be described in [E1] to [E16].

[E1]

A plasma processing apparatus includes: a chamber; a plasma generator configured to generate plasma from a gas within the chamber; at least one temperature adjustment target having a flow path therein, the at least one temperature adjustment target constituting a part of the chamber or disposed within the chamber; and a supply configured to supply a heat transfer medium to the flow path, the supply including a first tank configured to store the heat transfer medium therein and connected to the flow path via a first pipe, a second tank configured to store the heat transfer medium therein, and connected to the flow path via a second pipe and connected to the first tank via a third pipe, the second tank being disposed at a position lower than a position of the first tank, a pump connected between the third pipe and the second tank and configured to pump the heat transfer medium stored in the second tank to the first tank via the third pipe, and a heat exchanger disposed upstream of the flow path and configured to adjust a temperature of the heat transfer medium.

[E2]

In the plasma processing apparatus according to E1, the heat transfer medium is a heat transfer liquid.

[E3]

In the plasma processing apparatus according to E1 or E2, the first pipe is connected to the first tank at a position higher than a position of the flow path, and the second pipe is connected to the second tank at a position lower than the position of the flow path.

[E4]

In the plasma processing apparatus according to any one of E1 to E3, the supply further includes a first flow rate meter configured to measure a first flow rate of the heat transfer medium in the first pipe, a second flow rate meter configured to measure a second flow rate of the heat transfer medium in the third pipe, and a controller configured to control the pump to reduce or eliminate a difference between the first flow rate and the second flow rate.

[E5]

In the plasma processing apparatus according to E4, the supply further includes a liquid level sensor configured to measure a height position of a liquid level of the heat transfer medium in one of the first tank and the second tank, and the controller is configured to control the pump to maintain the height position of the liquid level measured by the liquid level sensor within a designated range.

[E6]

In the plasma processing apparatus according to E5, the controller is configured to control the pump to reduce or eliminate the difference between the first flow rate and the second flow rate when the height position of the liquid level measured by the liquid level sensor is within the designated range, and control the pump to maintain the height position of the liquid level measured by the liquid level sensor within the designated range when the height position of the liquid level measured by the liquid level sensor is outside the designated range.

[E7]

In the plasma processing apparatus according to any one of E1 to E3, the supply further includes a flow rate adjustment valve connected between the pump and the first tank, a first flow rate meter configured to measure a first flow rate of the heat transfer medium in the first pipe, a second flow rate meter configured to measure a second flow rate of the heat transfer medium in the third pipe, and a controller configured to control the flow rate adjustment valve to reduce or eliminate a difference between the first flow rate and the second flow rate.

[E8]

In the plasma processing apparatus according to E7, the supply further includes a liquid level sensor configured to measure a height position of a liquid level of the heat transfer medium in one of the first tank and the second tank, and the controller is configured to control the flow rate adjustment valve to maintain the height position of the liquid level measured by the liquid level sensor within a designated range.

[E9]

In the plasma processing apparatus according to E8, the controller is configured to control the flow rate adjustment valve to reduce or eliminate the difference between the first flow rate and the second flow rate when the height position of the liquid level measured by the liquid level sensor is within the designated range, and control the flow rate adjustment valve to maintain the height position of the liquid level measured by the liquid level sensor within the designated range when the height position of the liquid level measured by the liquid level sensor is outside the designated range.

[E10]

The plasma processing apparatus according to any one of E1 to E9, further includes: a substrate support disposed within the chamber, and the at least one temperature adjustment target includes the substrate support.

[E11]

The plasma processing apparatus according to any one of E1 to E9, further includes: a substrate support disposed within the chamber; and an upper electrode disposed above the substrate support, and the at least one temperature adjustment target includes at least one of the substrate support and the upper electrode.

[E12]

In the plasma processing apparatus according to any one of E1 to E11, the at least one temperature adjustment target includes a sidewall of the chamber.

[E13]

In the plasma processing apparatus according to any one of E1 to E12, the first tank and the second tank are disposed outside the chamber so as to set a pressure inside each of the first tank and the second tank to be an atmospheric pressure.

[E14]

In the plasma processing apparatus according to any one of E1 to E13, the supply further includes at least one valve connected between the second pipe and the second tank.

[E15]

In the plasma processing apparatus according to E14, the at least one valve includes a shutoff valve and/or a flow rate adjustment valve.

[E16]

In the plasma processing apparatus according to E15, the shutoff valve and the flow rate adjustment valve are connected in series between the second pipe and the second tank.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A plasma processing apparatus comprising:
a chamber;
a plasma generator configured to generate plasma from a gas within the chamber;
a temperature adjustment target having a flow path therein, the temperature adjustment target constituting a part of the chamber or disposed within the chamber; and
a supply configured to supply a heat transfer medium to the flow path, the supply comprising:
a first tank configured to store the heat transfer medium therein, the first tank being and connected to the flow path via a first pipe;
a second tank configured to store the heat transfer medium therein, the second tank being connected to the flow path via a second pipe and being connected to the first tank via a third pipe, the second tank being disposed at a position lower than a position of the first tank;
a pump connected between the third pipe and the second tank, the pump being configured to pump the heat transfer medium stored in the second tank to the first tank via the third pipe; and
a heat exchanger disposed upstream of the flow path and configured to adjust a temperature of the heat transfer medium.

2. The plasma processing apparatus according to claim 1, wherein the heat transfer medium is a heat transfer liquid.

3. The plasma processing apparatus according to claim 1, wherein:
the first pipe is connected to the first tank at a position higher than a position of the flow path, and
the second pipe is connected to the second tank at a position lower than the position of the flow path.

4. The plasma processing apparatus according to claim 1, wherein
the supply further comprises:
a first flow rate meter configured to measure a first flow rate of the heat transfer medium in the first pipe;
a second flow rate meter configured to measure a second flow rate of the heat transfer medium in the third pipe; and
a circuitry configured to control the pump to reduce or eliminate a difference between the first flow rate and the second flow rate.

5. The plasma processing apparatus according to claim 4, wherein:
the first flow rate meter is disposed on the first pipe between the first tank and the temperature adjustment target, and
the second flow rate meter is disposed on the third pipe between the first tank and the second tank.

6. The plasma processing apparatus according to claim 4, wherein:
the supply further comprises a liquid level sensor configured to measure a height position of a liquid level of the heat transfer medium in one of the first tank and the second tank, and
the circuitry is configured to control the pump to maintain the height position of the liquid level measured by the liquid level sensor within a designated range.

7. The plasma processing apparatus according to claim 4, wherein:
the supply further comprises a liquid level sensor configured to measure a height position of a liquid level of the heat transfer medium in one of the first tank and the second tank, and
the circuitry is configured to:
control the pump to reduce or eliminate the difference between the first flow rate and the second flow rate when the height position of the liquid level measured by the liquid level sensor is within the designated range, and
control the pump to maintain the height position of the liquid level measured by the liquid level sensor within the designated range when the height position of the liquid level measured by the liquid level sensor is outside the designated range.

8. The plasma processing apparatus according to claim 1, wherein the supply further comprises:
a flow rate adjustment valve connected between the pump and the first tank;
a first flow rate meter configured to measure a first flow rate of the heat transfer medium in the first pipe;
a second flow rate meter configured to measure a second flow rate of the heat transfer medium in the third pipe; and
a circuitry configured to control the flow rate adjustment valve to reduce or eliminate a difference between the first flow rate and the second flow rate.

9. The plasma processing apparatus according to claim 8, wherein:
the supply further comprises a liquid level sensor configured to measure a height position of a liquid level of the heat transfer medium in one of the first tank and the second tank, and
the circuitry is configured to control the flow rate adjustment valve to maintain the height position of the liquid level measured by the liquid level sensor within a designated range.

10. The plasma processing apparatus according to claim 8, wherein:
the supply further comprises a liquid level sensor configured to measure a height position of a liquid level of the heat transfer medium in one of the first tank and the second tank, and
the circuitry is configured to:
control the flow rate adjustment valve to reduce or eliminate the difference between the first flow rate and the second flow rate when the height position of the liquid level measured by the liquid level sensor is within the designated range, and
control the flow rate adjustment valve to maintain the height position of the liquid level measured by the liquid level sensor within the designated range when the height position of the liquid level measured by the liquid level sensor is outside the designated range.

11. The plasma processing apparatus according to claim 1, further comprising:
a substrate support disposed within the chamber,
wherein the temperature adjustment target includes the substrate support.

12. The plasma processing apparatus according to claim 11, further comprising:
an upper electrode disposed above the substrate support,
wherein the temperature adjustment target further includes the upper electrode.

13. The plasma processing apparatus according to claim 1, wherein the temperature adjustment target includes a sidewall of the chamber.

14. The plasma processing apparatus according to claim 1, wherein the first tank and the second tank are disposed outside the chamber so as to set a pressure inside each of the first tank and the second tank to atmospheric pressure.

15. The plasma processing apparatus according to claim 1, wherein:
the supply further comprises at least one valve connected between the second pipe and the second tank, and
the at least one valve includes a shutoff valve and/or a flow rate adjustment valve.

16. The plasma processing apparatus according to claim 15, wherein:
the at least one valve includes the shutoff valve and the flow rate adjustment valve, and
the shutoff valve and the flow rate adjustment valve are connected in series between the second pipe and the second tank.

17. A plasma processing apparatus comprising:
a chamber;
a plasma generator configured to generate plasma from a gas within the chamber;
a temperature adjustment target including a base having a flow path therein, the temperature adjustment target constituting a part of the chamber or disposed within the chamber; and
a supply configured to supply a heat transfer medium to the flow path, the supply comprising:
a first tank configured to store the heat transfer medium therein, the first tank being connected to the flow path via a first pipe;
a second tank configured to store the heat transfer medium therein, the second tank being connected to the flow path via a second pipe and the second tank being connected to the first tank via a third pipe;
a pump connected to the third pipe, the pump being configured to pump the heat transfer medium;
a first flow rate adjustment valve connected between the pump and the first tank or connected between the second tank and the temperature adjustment target, and
a heat exchanger disposed upstream of the flow path and configured to adjust a temperature of the heat transfer medium.

18. The plasma processing apparatus according to claim 17, wherein the second tank is positioned lower than the first tank to reduce a pressure of the heat transfer medium supplied to the temperature adjustment target and prevent deformation of the temperature adjustment target.

19. The plasma processing apparatus according to claim 17, wherein:
the first flow rate adjustment valve is connected between the pump and the first tank, and
the supply further includes a second flow rate adjustment valve connected between the second tank and the temperature adjustment target.

20. The plasma processing apparatus according to claim 19, wherein the supply further includes circuitry configured to control the first flow rate adjustment valve and the second flow rate adjustment valve to maintain an equal flow rate of the heat transfer medium in the first pipe and the second pipe.
